(19) United States
(12) Patent Application Publication
(10) Pub. No.: US 2026/0186399 A1
(43) Pub. Date: Jul. 2, 2026

(54) METHOD FOR DETERMINING DIVISION PATTERN OF RETICLE AND RETICLE

(71) Applicant: Absolics Inc., Covington, GA (US)

(72) Inventors: SeHan YUN, Covington, GA (US); Tae Kyoung KIM, Covington, GA (US); Hideto MORI, Covington, GA (US)

(73) Assignee: Absolics Inc., Covington, GA (US)

(21) Appl. No.: 19/433,070

(22) Filed: Dec. 26, 2025

Related U.S. Application Data
(60) Provisional application No. 63/739,106, filed on Dec. 26, 2024.
(60) Provisional application No. 63/739,107, filed on Dec. 26, 2024.

(51) Int. Cl. G03F 1/00

(52) U.S. Cl. CPC G03F 1/00

(57) ABSTRACT

An embodiment provides a method for partitioning a target reticle into a plurality of unit reticles based on a unit-bare reticle and a structure for interconnecting the partitioned unit reticles to ensure pattern continuity. In the partitioning method, boundary lines are extracted based on wiring patterns and an outermost outline, and are then connected to generate candidate sets of single closed curves that collectively cover the entire target reticle. From these candidates, only the sets that can be arranged within the unit-bare reticle are retained, and a unit reticle set is determined by selecting the candidates in ascending order of the number of single closed curves. Adjacent first and second unit reticles have respective connection surfaces that are in contact with each other, and wire alignment and continuity between the unit reticles are reliably achieved by linear patterns passing through the connection surfaces and stitching linear patterns in stitching regions.

### CROSS-REFERENCE TO RELATED APPLICATION

This application claims priority of U.S. Provisional Patent Applications No. 63/739,107 filed on Dec. 26, 2024, and No. 63/739,106 filed on Dec. 26, 2024, the entire disclosures of which are hereby incorporated by reference for all purposes.

### BACKGROUND

### Technical Field

Embodiments relate to a method for determining a division pattern of a reticle which, when a large reticle is configured by combining a plurality of smaller reticles, efficiently defines boundaries of the respective smaller reticles so as to obtain a reticle having high accuracy and high integration density, and the like.

Embodiments also relate to a reticle prepared by arranging two or more divided unit reticles side by side, and, while two or more unit reticles are applied, fatal errors such as short-circuiting of wirings are minimized.

### Description of Related Art

In manufacturing a packaging substrate, a photolithography process is applied while forming a circuit pattern disposed on a substrate. With the possibility of adopting glass substrates and the like, large-area substrates may now be used. However, a problem arises in that a circuit-pattern design may be larger than a reticle size applicable to the photolithography process. In such cases, the circuit-pattern design may be divided into a plurality of regions for processing. Each divided reticle corresponding to the multi-region circuit-pattern design therefore has a cut portion at its boundary.

The foregoing background art comprises technical information that the inventor either possessed for deriving the present invention or acquired in the course of doing so, and thus cannot necessarily be regarded as prior art that was disclosed to the general public before the filing of the present application.

Related art comprises Korean Patent Laid-Open Publication No. 10-2024-0019240, Korean Patent Laid-Open Publication No. 10-2016-0142252, and U.S. Pat. No. 11,803,013.

### SUMMARY

In some embodiments, a method for determining a division pattern of a reticle which, when a large reticle is configured by combining a plurality of smaller reticles, efficiently defines boundaries of the respective smaller reticles so as to obtain a reticle having high accuracy and high integration density is provided.

In some embodiments, a reticle comprising a plurality of unit reticles, which can substantially prevent misalignment of wirings in boundary regions of the reticle is provided.

According to the embodiments, a method of determining a division pattern of a reticle, the method including: a partitioning process of dividing a reticle pattern so that a target reticle, which is larger in size than a unit bare reticle, is realized by applying the unit bare reticle.

The method may comprise: a basic operation of acquiring target-reticle data by inputting a wiring pattern and an outermost boundary corresponding to one conductive layer to be formed; a line-extraction operation of extracting, within the target-reticle data, a plurality of boundary lines that are disposed in spaces where no wires of the wiring pattern are placed or correspond to the outermost boundary of the target-reticle data; an area-extraction operation of generating, as a candidate pool, a plurality of single-closed-curve sets, each set covering an entire area of the target-reticle data with a plurality of single closed curves obtained by connecting the plurality of boundary lines; a verification operation of excluding, from the candidate pool, any single-closed-curve set in which at least one single closed curve is not placed within the unit bare reticle; and an output operation of outputting the single-closed-curve sets from the candidate pool in ascending order of the number of single closed curves contained therein.

The method may further comprise preparing a unit-reticle set having an external shape corresponding to the single-closed-curve set, thereby realizing the divided target reticle.

The plurality of boundary lines may be substantially straight.

The wiring pattern may include a linear-wire pattern and a via-pad-type wire pattern.

The line-extraction operation may include: first-boundary-extraction procedure of extracting a first-type boundary line at the center between a first linear wire and an adjacent second linear wire; second-boundary-extraction procedure of extracting, between a third linear wire and an adjacent via-pad-type wire, a second-type boundary line along the third linear wire at a constant interval therefrom; and third-boundary-extraction procedure of extracting a third-type boundary line disposed between adjacent via-pad-type wires and connecting, with the shortest distance, opposite ends of the first-type boundary line, opposite ends of the second-type boundary line, or a portion of the outermost boundary.

If no single-closed-curve set is derived in the area-extraction operation, an extended-boundary-extraction procedure may be performed to extract an extended first-type boundary line and an extended second-type boundary line, each obtained by extending the first-type boundary line and the second-type boundary line, respectively, in straight lines to a point penetrating one wire; thereafter, the area-extraction operation may be performed again based on the plurality of boundary lines including the extended first-type boundary line, the extended second-type boundary line, and the third-type boundary line.

If no single-closed-curve set is derived in the re-performed area-extraction operation, the extended-boundary-extraction operation may be applied such that the extended boundary lines are extended to a point penetrating n wires, and the extended-boundary-extraction operation and the area-extraction operation are repeatedly performed, wherein n may be sequentially applied as an integer of 2 or more.

The output operation may further output whether the extended-boundary-extraction operation has been performed.

If the area-extraction operation fails to derive a single-closed-curve set, an extended-boundary-line extraction procedure is carried out, in which an extended first-type boundary line and an extended second-type boundary line are extracted by extending the first-type boundary line and the second-type boundary line, respectively, in a straight line to a point that penetrates one wire; thereafter, the area-extraction operation may be performed again on the basis of a plurality of boundary lines including the extended first-type boundary line, the extended second-type boundary line, and the third-type boundary line.

If the re-executed area-extraction operation still fails to derive a single-closed-curve set, the extended-boundary-line extraction procedure is applied once again so that the extended boundary lines are prolonged to a point that penetrates n wires; the extended-boundary-line extraction procedure and the area-extraction operation are then repeated, and n may be sequentially applied as an integer of 2 or greater.

The output operation may further include outputting whether the extended-boundary-line extraction procedure has been performed.

The output operation may output p single-closed-curve sets, wherein p may be an integer of 1 to 10.

In the first-boundary-extraction procedure, the space between the first linear wire and the second linear wire may have a width at least three times the smaller one of the widths of the first and second linear wires.

In the output operation, the number of single closed curves contained in one single-closed-curve set may be two or more and ten or less.

The target reticle has a rectangular shape whose shorter one of width and length is A, and the unit bare reticle has a rectangular shape whose shorter one of width and length is B, and A may be at least 1.15 times B.

According to the embodiments, embodiment includes a reticle pattern configured such that a target reticle having a size larger than that of a unit reticle is implemented by applying unit reticles. The reticle comprises a first unit reticle and a second unit reticle that are located adjacent to each other, the first unit reticle having a first-to-second connection surface that is in contact with the second unit reticle, and the second unit reticle having a second-to-first connection surface that is in contact with the first unit reticle.

The first unit reticle and the second unit reticle are connected to each other and have a linear pattern passing through the first-to-second connection surface and the second-to-first connection surface. A portion of the linear pattern disposed on the first-to-second connection-surface side of the first unit reticle is a first-side linear pattern, and a portion of the linear pattern disposed on the second-to-first connection-surface side of the second unit reticle is a second-side linear pattern. A first-to-second stitching region is disposed at an edge of the first-to-second connection surface of the first unit reticle.

A pattern disposed in the first-to-second stitching region and connected to the first-side linear pattern is a first-to-second stitching linear pattern, and the first-to-second stitching linear pattern may have one end directly connected to the first-side linear pattern and the other end directly connected to the first-to-second connection surface.

The first-to-second stitching linear pattern may comprise linear patterns extending from the one end to the other end, with distances between the linear patterns as a whole gradually increasing, and a width of the linear pattern at the other end may be larger than a width of the linear pattern at the one end.

A second-to-first stitching region is disposed at an edge on the second-to-first connection-surface side of the second unit reticle, and a pattern disposed in the second-to-first stitching region and connected to the second-side linear pattern is a second-to-first stitching linear pattern. The second-to-first stitching linear pattern may have one end directly connected to the second-side linear pattern and the other end directly connected to the second-to-first connection surface.

The second-to-first stitching linear pattern may comprise linear patterns extending from the one end to the other end, with distances between the linear patterns as a whole gradually increasing, and a width of the linear pattern at the other end may be larger than a width of the linear pattern at the one end.

When the first unit reticle and the second unit reticle come into contact with each other, the other end of the first-to-second stitching linear pattern and the other end of the second-to-first stitching linear pattern may come into contact with each other, so that the first-side linear pattern and the second-side linear pattern may be connected.

The width of the linear pattern at the other end may be obtained by expanding the width of the linear pattern at the one end by 1 μm to 5 μm on each of both sides.

The width of the linear pattern at the other end may be obtained by expanding the width of the linear pattern at the one end by 1 μm to 4 μm on each of both sides.

A linear pattern extending from the one end to the other end may have a constant width and may have a semicircular or semi-elliptical shape at the other end.

A linear pattern extending from the one end to the other end may be formed such that its width gradually increases from the one end toward the other end.

A distance between an edge of a first-side pad and the first-to-second connection surface may be 2.5 μm or more.

The reticle may have a rectangular shape and may be 10 cm or more on a longer side of width and length, and the first unit reticle may be 8 cm or less on a shorter side of width and length.

The first unit reticle may further comprise a first-side via pattern.

The first-side via pattern may comprise a first-side via and a first-side pad surrounding the first-side via.

A diameter of the first-side pad may be 3 μm to 15 μm larger than a diameter of the first-side via.

A distance between the first-side pad and a neighboring other via pad or another linear pattern may be 2 μm or more.

### BRIEF DESCRIPTION OF THE DRAWINGS

FIG. 1 is a conceptual plan view exemplarily illustrating a conventional target reticle and a unit bare reticle described herein.

FIG. 2 is a conceptual view illustrating boundary lines according to an embodiment.

FIG. 3 is a conceptual view illustrating the placement of single closed curves within a unit bare reticle according to an embodiment.

FIG. 4 is a conceptual view illustrating implementation of a target reticle through unit reticles whose outer shapes correspond to single closed curves, according to an embodiment.

FIG. 5 is a conceptual view illustrating a target reticle comprising a set of unit reticles and stitching lines, according to an embodiment.

FIG. 6 is a drawing exemplarily illustrating a stitching portion according to an embodiment.

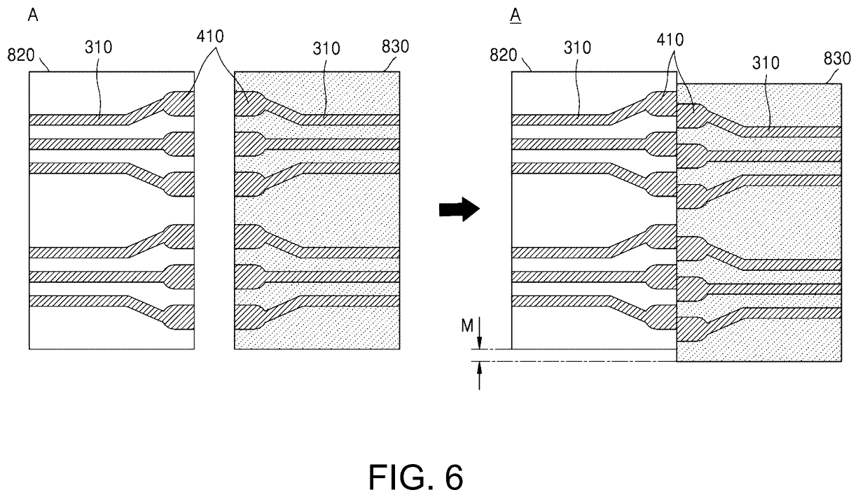

FIG. 7 is a view schematically illustrating a part of a reticle according to an embodiment.

FIG. 8A is a conceptual view illustrating a state in which a first unit reticle and a second unit reticle are in contact with each other according to an embodiment, and FIG. 8B is a conceptual view illustrating an example according to a conventional case.

FIG. 9 is a conceptual view illustrating an example in which blind vias are disposed according to an embodiment.

### DESCRIPTION OF THE EMBODIMENTS

Hereinafter, exemplary embodiments will be described in detail with reference to the accompanying drawings so that those skilled in the art can readily carry out the present invention. The present invention, however, may be embodied in various different forms and is not limited to the embodiments set forth herein. Throughout the entire specification, identical reference numerals denote like parts.

Throughout the present specification, the term “a combination thereof” contained in a Markush-type expression refers to one or more mixtures or combinations selected from the group of components recited in the Markush-type expression, and comprises at least one component selected from the group.

Throughout the present specification, terms such as “first,” “second,” or “A,” “B” are used only to distinguish identical terms from each other. Unless clearly indicated otherwise by the context, singular expressions shall be construed to comprise plural expressions as well.

In the present specification, the notation “˜group” may mean that the compound comprises a compound corresponding to “˜” or a derivative thereof within the molecule.

In the present specification, the expression that “B is positioned on A” means that B is placed directly in contact with A or that B is placed on A with another layer interposed therebetween; it is not limited to the interpretation that B must contact the surface of A.

In the present specification, the expression that “B is connected to A” means that A and B are directly connected or are connected via another component interposed therebetween; unless otherwise specified, it is not limited to an interpretation that A and B are directly connected.

Unless specifically stated otherwise, singular expressions in the present specification shall be interpreted to comprise both singular and plural meanings as dictated by the context.

In the drawings, the shapes, relative sizes, and angles of the respective components may be exaggerated for illustrative clarity, and the scope of rights shall not be construed as being limited to the drawings.

In the present specification, the phrase that “A and B are adjacent” means that A and B are either in contact with each other or located close to each other without direct contact; unless otherwise specified, it is not limited to the interpretation that A and B must be in contact.

Commercial-scale fabrication of packaging substrates that comprise a glass core is now

under way. Unlike laboratory-scale production, commercial manufacturing requires automated production equipment and multi-stage inspection facilities. The glass core used for the packaging substrate is a plate glass for semiconductors, and plate glass of considerably large size can be employed. For example, a rectangular glass core having one side of 10 cm or greater may be used. By contrast, the size of commercially available reticles is about 8 cm, which is smaller than the glass-core size. Accordingly, in order to form one wiring layer on the glass core, two or more reticles must be used together.

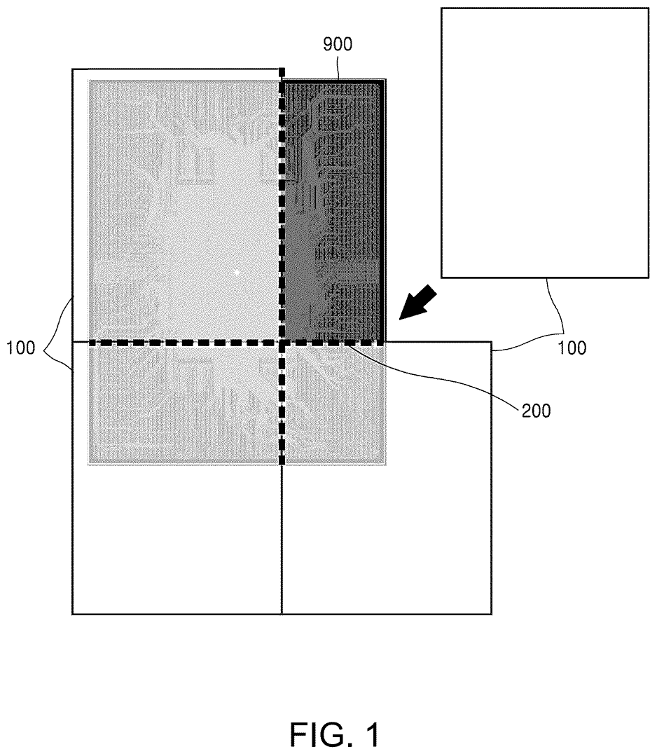

FIG. 1 is a conceptual plan view that exemplarily illustrates a conventional target reticle and a unit bare reticle described herein, and the conventional technology will be explained with reference to FIG. 1.

The large reticle to be obtained is referred to as the target reticle 900, and the commercially obtainable reticle is referred to as the unit bare reticle 100. The target reticle 900 can be obtained by arranging two or more unit bare reticles 100. In this case, a boundary arises between adjacent unit bare reticles 100, and this boundary is designated as the boundary 200.

The boundary 200 lies within the plane of the target reticle 900, and the target reticle 900 carries a pattern corresponding to the wiring pattern of the conductive layer on the packaging substrate.

The boundary 200 is adjacent to, or passes through, the wiring pattern. However, in the manufacturing process a positional error (margin) may occur in the placement of the unit bare reticles 100. Taking this into account, errors can occur in the wiring pattern at the boundary 200. Such errors may cause an open or short circuit in wires that ought to be continuous, or may undesirably connect wires that should remain isolated.

The inventors have proposed the embodiments described herein in order to reduce the possibility of such errors and to enable efficient application of reticles with high accuracy.

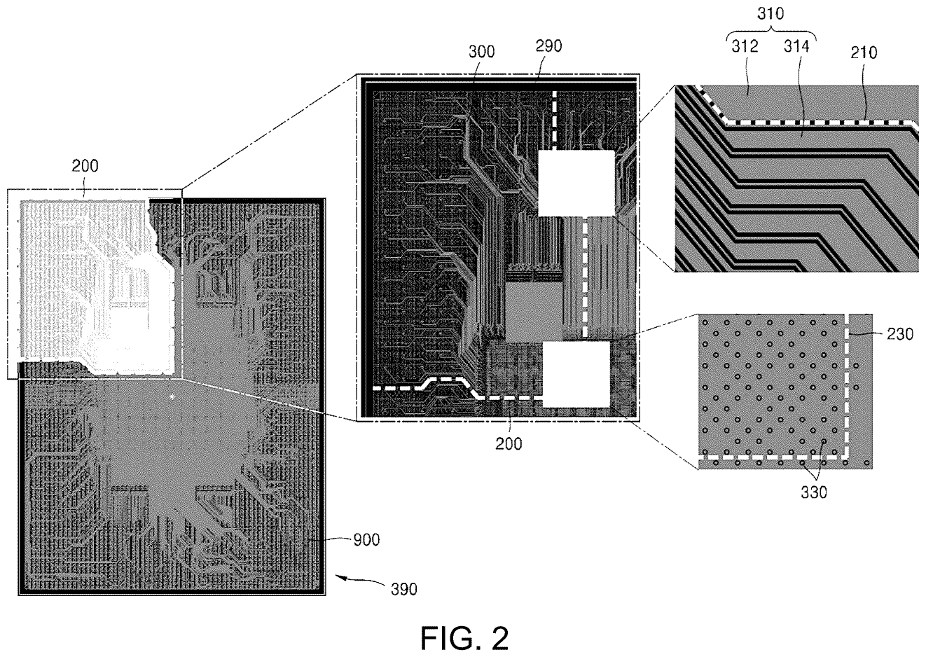

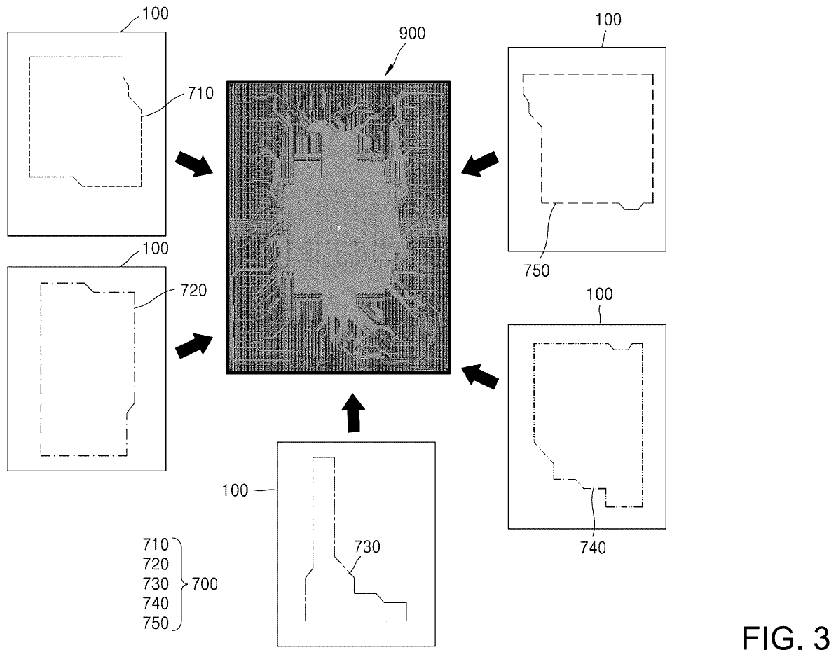

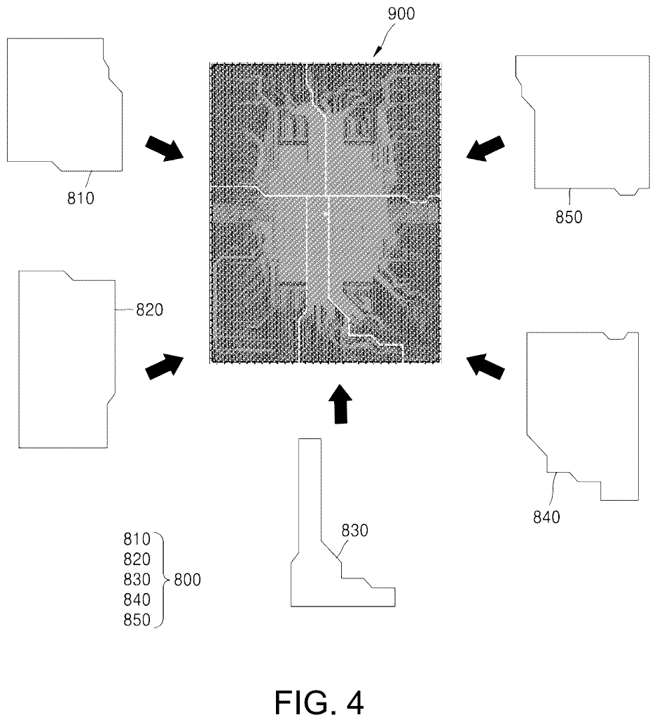

FIG. 2 is a conceptual view illustrating boundary lines according to an embodiment, FIG. 3 is a conceptual view illustrating, according to an embodiment, the placement of single closed curves in a unit bare reticle, and FIG. 4 is a conceptual view illustrating, according to an embodiment, implementation of a target reticle through unit reticles having the outer shapes of the single closed curves. With reference to FIGS. 2 to 4, the embodiment will be described in more detail.

In come embodiments, a method for determining a division pattern of a reticle comprises a method of partitioning a reticle pattern such that a target reticle 900 larger than a unit bare reticle 100 is realized by applying the unit bare reticle 100, and comprises a basic operation, a line-extraction operation, an area-extraction operation, a verification operation, and an output operation.

The basic operation is an operation of acquiring target-reticle data by inputting a wiring pattern 300 and an outermost boundary 390 corresponding to one conductive layer to be formed.

The wiring pattern is digitized in consideration of the lithography method to be applied and is obtained, and is used as fundamental information in the subsequent operations.

The outermost boundary 390 is included as part of the boundary lines 200 described later.

The wiring patterns 300 are used as reference data for setting the positions of the boundary lines 200.

The wiring pattern 300 comprises a linear-wire pattern 310 and a via-pad-type wiring pattern 330.

The line-extraction operation is an operation of extracting, within the target-reticle data, a plurality of boundary lines 200 that are placed in spaces where no wires of the wiring pattern 300 are present, or correspond to the outermost boundary 390 of the target-reticle data.

When linear-wire patterns 310 are arranged side by side, a boundary line is defined between them. When a linear-wire pattern 310 and a via-pad-type wiring pattern 330 are arranged side by side, a boundary line is defined along the shape of the linear-wire pattern 310. When via-pad-type wiring patterns 330 are arranged, an extension of the surrounding boundary line is defined so as to lie between the via-pad-type wiring patterns 330.

Specifically, the line-extraction operation comprises: a first-boundary-extraction procedure that extracts a first-type boundary line 210 at the midpoint between a first linear wire 312 and an adjacent second linear wire 314; a second-boundary-extraction procedure that extracts a second-type boundary line along a third linear wire and at a fixed spacing therefrom, the line being disposed between the third linear wire and an adjacent via-pad-type wire; and a third-boundary-extraction procedure that extracts a third-type boundary line 230, which is placed between adjacent via-pad-type wires and connects, by the shortest path, opposite ends of the first-type boundary line 210, opposite ends of the second-type boundary line 220, or portions of the outermost boundary 390.

In the first-boundary-extraction procedure, the space between the first linear wire and the second linear wire may have a width at least three times, or five times, the smaller of the widths of the first and second linear wires.

The plurality of boundary lines 200 are substantially straight. The boundary lines derived with reference to the wiring patterns may have their ends connected to one another, and the outermost boundary 390 may be connected to the boundary lines at an intermediate portion rather than at its ends.

The area-extraction operation is an operation of forming a candidate pool by generating a plurality of single-closed-curve sets 700, each set comprising several single closed curves 710 obtained by connecting the boundary lines 200 and covering the entire area of the target-reticle data.

A plurality of the boundary lines 200 are disposed between the wiring patterns 300; they are connected so as not to touch or intersect the ends of closely spaced boundary lines or the wiring patterns, thereby enabling the boundary lines to join together into single closed curves.

The single closed curves can partition the target reticle into regions, and a collection of such partitioning single closed curves is referred to as a single-closed-curve set 700.

Multiple single-closed-curve sets 700 may be generated, each of which undergoes a verification operation to determine whether it can be applied as a unit reticle.

The verification operation is an operation of excluding, from the candidate pool, any single-closed-curve set 700 in which at least one of the single closed curves 710 is not located within the unit bare reticle 100.

All of the single closed curves must lie inside the unit bare reticle in order to prepare a unit-reticle set having the outer shapes of the single closed curves; therefore, if any individual single closed curve of a set is not accommodated within the unit bare reticle, that set is removed.

The output operation is an operation that outputs the single-closed-curve sets 700 from the candidate pool in ascending order of the number of single closed curves 710 contained in each single-closed-curve set 700.

A target reticle 900 must be configured from a unit-reticle set 800, and each unit reticle is realized as a unit bare reticle 100. The outer shape of every unit reticle is made identical to that of its corresponding single closed curve. Accordingly, if any single closed curve of a single-closed-curve set cannot be placed within the unit bare reticle, that set cannot be used and must therefore be excluded from the candidate pool.

In the output operation, the number of single closed curves 710 contained in one single-closed-curve set 700 may be two or more, three or more, four or more, or five or more. The number may be 20 or less, 18 or less, 15 or less, 13 or less, or 10 or less.

The output operation comprises outputting multiple single-closed-curve sets 700. By way of example, the number of single-closed-curve sets output may be from 1 to 10, but is not limited thereto.

However, the above number may vary depending on the size of the target reticle and the size of the unit bare reticle.

For example, when the target reticle 900 is rectangular and its shorter side is A, and the unit bare reticle 100 is rectangular and its shorter side is B, A may be at least 1.15 times B.

By applying the foregoing method, it is possible to prepare a unit-reticle set 800 whose outer shapes correspond to the single-closed-curve set 700 and thereby to implement the divided target reticle 900 efficiently.

If the area-extraction operation fails to derive a single-closed-curve set 700, an extended-boundary-line extraction procedure is carried out, in which an extended first-type boundary line and an extended second-type boundary line are extracted by extending the first-type boundary line 210 and the second-type boundary line straight to a point that penetrates one wire; thereafter, the area-extraction operation may be performed again on the basis of a plurality of boundary lines comprising the extended first-type boundary line, the extended second-type boundary line, and the third-type boundary line 230.

If the re-performed area-extraction operation still fails to derive a single-closed-curve set 700, the extended-boundary-line extraction procedure is applied again so that the extended boundary lines are prolonged to a point that penetrates n wires; the extended-boundary-line extraction procedure and the area-extraction operation are then repeated, and n may be sequentially applied as an integer of 2 or greater.

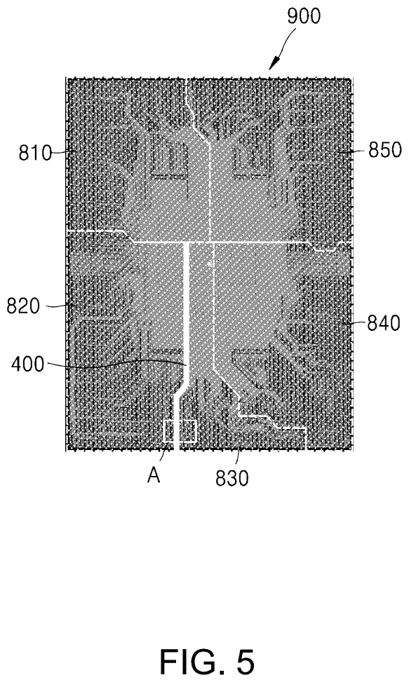

When the extended boundary lines are extracted and the area-extraction operation is performed, a stitching line 400 may be provided, as shown in FIG. 5.

The stitching line 400 is a boundary line that comprises a point where at least a portion of the wiring pattern is cut. A stitching pattern 410 is disposed on the boundary line at that cutting point.

When two or more reticles are arranged to form a large target reticle, an alignment error may occur in the placement of the individual reticles (unit reticles). In the proposed environment, where processes are carried out using a robot arm or the like, a certain level of alignment error (M, miss-alignment) is regarded as a normal process margin. Therefore, the stitching line is arranged in consideration of this margin.

The stitching pattern 410 has a line width and spacing greater than those of the wiring pattern on both sides of the point where the wiring pattern is cut along the boundary line. For example, when the line width and spacing of the wiring pattern are each 2 μm, the line width and spacing of the stitching pattern 410 are modified to 7 μm. In other words, approximately 4 μm—about 2 μm on each side—is added to the wiring-pattern line width so that a thicker line width is applied, and the line width and spacing are correspondingly modified. The portion of the wiring pattern reflecting this modification constitutes the stitching pattern 410, and this stitching pattern is applied where necessary between the unit reticles.

Accordingly, a complex large-area wiring pattern can be implemented accurately and efficiently.

A reticle according to another embodiment comprises: a target reticle having a wiring pattern corresponding to at least one conductive layer among the conductive layers of a substrate; a unit-reticle set in which two or more unit reticles 810, 820 are arranged, the unit-reticle set dividing the target reticle; and a stitching line 400 disposed on the boundary between the two adjacent unit reticles 810, 820.

The two or more unit reticles 800 may comprise a first unit reticle 810 and a second unit reticle 820.

At least a portion of the outer edge of the first unit reticle 810 may contact at least a portion of the outer edge of the second unit reticle 820.

By way of example, five unit reticles 800 may comprise a first unit reticle 810, a second unit reticle 820, a third unit reticle 830, a fourth unit reticle 840, and a fifth unit reticle 850 (see FIG. 4). The first unit reticle 810, the second unit reticle 820, the third unit reticle 830, the fourth unit reticle 840, and the fifth unit reticle 850 each share a boundary line with an adjacent reticle.

When the wiring pattern passes through the boundary line, a stitching line may be disposed at that portion. Detailed explanation of the stitching line overlaps with the description given above.

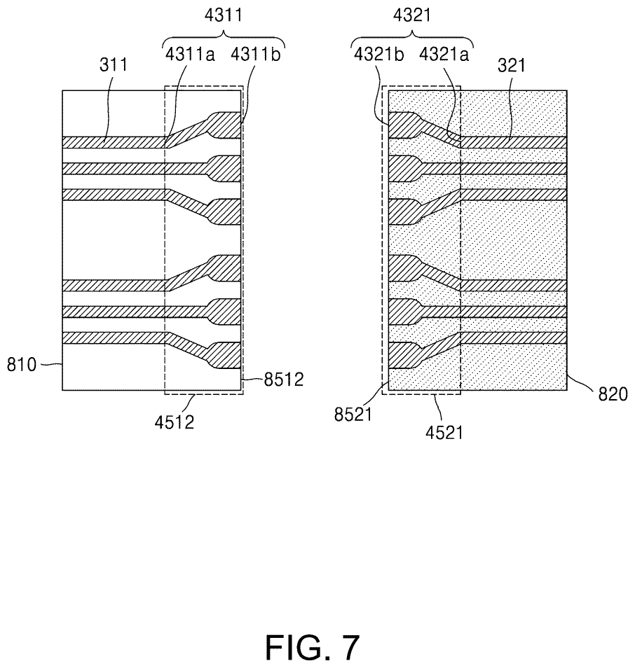

FIG. 7 is a view schematically illustrating a part of a reticle according to an embodiment,

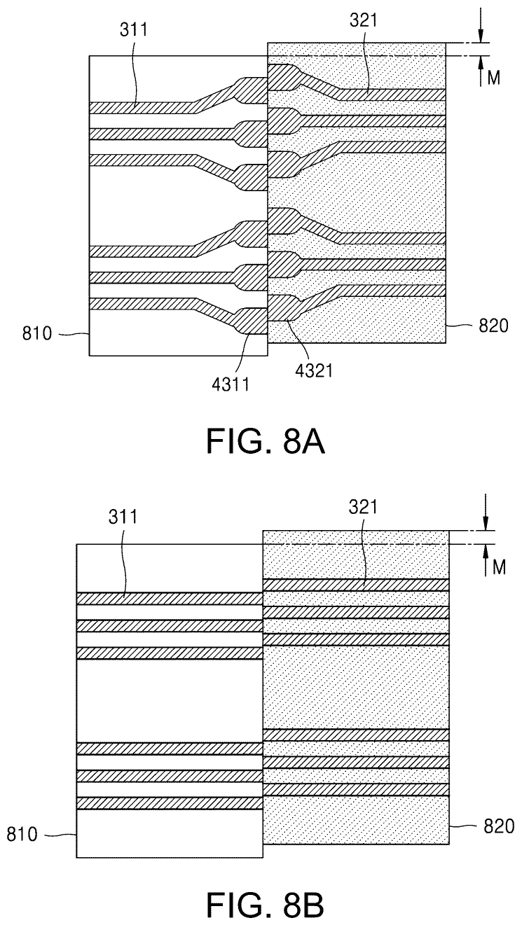

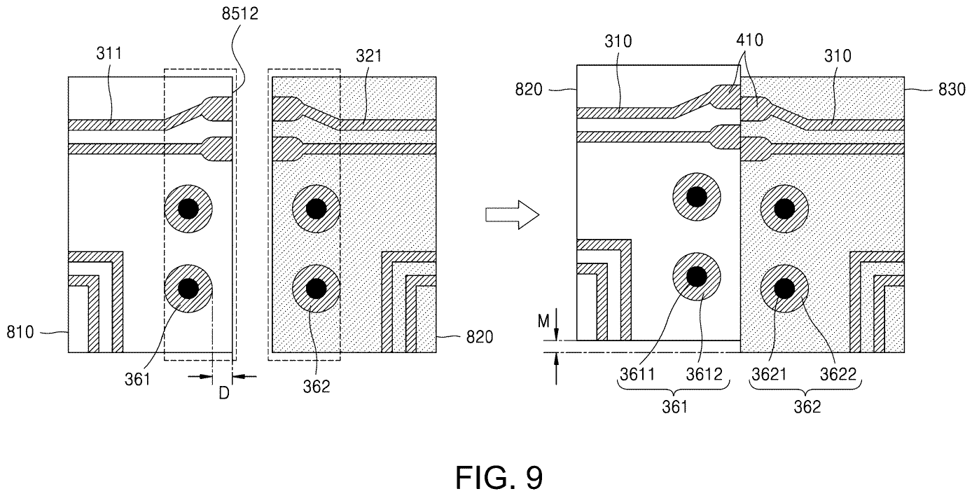

FIG. 8A is a conceptual view illustrating a state in which a first unit reticle and a second unit reticle are in contact with each other according to an embodiment, FIG. 8B is a conceptual view illustrating an example according to a conventional case, and FIG. 9 is a conceptual view illustrating an example in which blind vias are disposed according to an embodiment.

Hereinafter, the embodiment will be described in more detail with reference to FIGS. 7, 8A, and 9.

In some embodiments, a reticle 900 comprises a first unit reticle 810 and a second unit reticle 820 that are located adjacent to each other. Hereinafter, a case in which two reticles are provided will be described by way of example, but similarly, three or more, four or more, five or more, or six or more unit reticles may be applied. In addition, as necessary, 20 or fewer, or 18 or fewer, unit reticles may be applied.

The first unit reticle 810 has a first-to-second connection surface 8512 which is in contact with the second unit reticle 820. The second unit reticle 820 has a second-to-first connection surface 8521 which is in contact with the first unit reticle 810. These are lines at which neighboring unit reticles come into contact with each other, and, by way of example, a part of a rectangle is illustrated; however, each unit reticle may be formed as a polygon other than a rectangle depending on the design. For example, the connection surfaces may be arranged so as to cut wiring patterns to be placed to a minimum extent.

The first unit reticle 810 and the second unit reticle 820 are connected to each other and have a linear pattern passing through the first-to-second connection surface 8512 and the second-to-first connection surface 8521. It is preferable that an entire reticle 900 be configured such that, even when slight misalignment occurs when the unit reticles are placed, electrical open circuits and the like do not occur.

A portion of the linear pattern disposed on the first-to-second connection-surface 8512 side of the first unit reticle 810 is a first-side linear pattern 311, and a portion of the linear pattern disposed on the second-to-first connection-surface 8521 side of the second unit reticle 820 is a second-side linear pattern 321.

A first-to-second stitching region 4512 is disposed at an edge on the first-to-second connection-surface 8512 side of the first unit reticle 810, and a second-to-first stitching region 4521 is disposed at an edge on the second-to-first connection-surface 8521 side of the second unit reticle 820.

A pattern disposed in the first-to-second stitching region 4512 and connected to the first-side linear pattern 311 is a first-to-second stitching linear pattern 4311, and the first-to-second stitching linear pattern 4311 may have one end directly connected to the first-side linear pattern 311 and the other end directly connected to the first-to-second connection surface 8512.

A pattern disposed in the second-to-first stitching region 4521 and connected to the second-side linear pattern 321 is a second-to-first stitching linear pattern 4321, and the second-to-first stitching linear pattern 4321 may have one end directly connected to the second-side linear pattern 321 and the other end directly connected to the second-to-first connection surface 8521.

The first-to-second stitching linear pattern 4311 may comprise linear patterns extending from the one end 4311a to the other end 4311b, with distances between the linear patterns as a whole gradually increasing, and a width of the linear pattern at the other end 4311b may be larger than a width of the linear pattern at the one end 4311a. Such widening substantially prevents occurrence of short circuits even when misalignment occurs between two neighboring unit reticles.

A width of the linear pattern at the other end 4311b may be obtained by expanding the width of the linear pattern at the one end 4311a by 1 μm or more, 1.5 μm or more, 2 μm or more, 2.5 μm or more, or 2.8 μm or more on each of both sides. In addition, the width may be obtained by expanding the width by 5 μm or less, 4.5 μm or less, 4 μm or less, 3.5 μm or less, or 3.2 μm or less on each of both sides.

Since the widening means widening on each of both sides, for example, when a line of 2 μm is widened by 2 μm on each of both sides, the line becomes a line of 6 μm.

The linear pattern extending from the one end 4311a to the other end 4311b may have a constant width and may have a semicircular or semi-elliptical shape at the other end 4311b.

The linear pattern extending from the one end 4311a to the other end 4311b may be formed such that its width gradually increases from the one end 4311a toward the other end 4311b.

Similarly, a second-to-first stitching linear pattern 4321 may comprise linear patterns extending from the one end 4321a to the other end 4321b, with distances between the linear patterns as a whole gradually increasing, and a width of the linear pattern at the other end 4321b may be larger than a width of the linear pattern at the one end 4321a. Thus, even when miss alignment (M, miss alignment) occurs between two neighboring unit reticles, occurrence of short circuits can be more effectively prevented.

A width of the linear pattern at the other end 4321b may be obtained by expanding the width of the linear pattern at the one end 4321a by 1 μm or more, 1.5 μm or more, 2 μm or more, 2.5 μm or more, or 2.8 μm or more on each of both sides. In addition, the width may be obtained by expanding the width by 5 μm or less, 4.5 μm or less, 4 μm or less, 3.5 μm or less, or 3.2 μm or less on each of both sides.

Since the widening means widening on each of both sides, for example, when a line of 2 μm is widened by 2 μm on each of both sides, the line becomes a line of 6 μm.

The shape at the other end 4321b, and the configuration in which the width becomes thicker from the one end 4321a toward the other end 4321b, may be as described above.

When the first unit reticle 810 and the second unit reticle 820 come into contact with each other, the other end 4311b of the first-to-second stitching linear pattern 4311 and the other end 4321b of the second-to-first stitching linear pattern 4321 may come into contact with each other, so that the first-side linear pattern 311 and the second-side linear pattern 321 may be connected.

The first unit reticle 810 may further comprise a first-side via pattern 361.

By way of example, a case in which the first unit reticle 810 comprises the first-side via pattern 361 is described, but a second-side via pattern 362 may also be disposed in the second unit reticle 820.

The first-side via pattern 361 comprises a first-side via 3611 and a first-side pad 3612 surrounding the first-side via 3611.

In a reticle, a via pattern may suffer from an error in which its position is shifted during an exposure operation. Accordingly, it is preferable to arrange distances and the like in consideration thereof. In addition, a pad may be applied as a means for alleviating such positional error of the via.

A diameter of the first-side pad 3612 may be 3 μm or more, 3.5 μm or more, 4 μm or more, 4.5 μm or more, or 5 μm or more larger than a diameter of the first-side via 3611. In addition, the diameter may be 15 μm or less, 14 μm or less, 13 μm or less, 12 μm or less, 11 μm or less, 10 μm or less, 9 μm or less, 8μm or less, or 7 μm or less larger than the diameter of the first-side via 3611.

Since circular structures such as vias and pads may suffer from a shift phenomenon, a spacing for arranging these structures with respect to other structures is also important.

By way of example, a distance between the first-side pad 3612 and a neighboring other via pad or another linear pattern may be 2 μm or more, 2.5 μm or more, 3 μm or more, or 3.5 μm or more. In addition, the distance may be 12 μm or less, 11 μm or less, 10 μm or less, 9 μm or less, 8 μm or less, 7 μm or less, 6 μm or less, or 5 μm or less.

A distance (D) between an edge of the first-side pad 3612 and the first-to-second connection surface 8512 may be 2.5 μm or more, 3 μm or more, or 3.5 μm or more. In addition, the distance may be 12 μm or less, 11 μm or less, 10 μm or less, 9 μm or less, 8 μm or less, 7 μm or less, 6 μm or less, or 5 μm or less.

The reticle 900 may have a rectangular shape and may be 10 cm or more on a longer side of width and length.

The first unit reticle 810 may be 8 cm or less on a shorter side of width and length.

The reticle 900 may be a reticle of a size that is difficult to implement with a single bare reticle, and may be configured by arranging unit reticles, and, in this case, a stitching region as described above may be applied for the purpose of reducing errors such as short circuits.

The method for determining a division pattern of a reticle according to the embodiments makes it possible, when a large reticle is configured by combining a plurality of smaller reticles, to efficiently define boundaries of the respective smaller reticles and thereby provide a reticle having high accuracy and high integration density.

A reticle including a set of divided unit reticles according to the embodiments may provide a reticle which can efficiently divide a large-area reticle and substantially prevent misalignment of wirings near boundary lines.

Although preferred embodiments of the present invention have been described in detail above, the scope of rights of the present invention is not limited thereto, and various modifications and improved forms made by those skilled in the art using the basic concept of the present invention defined in the following claims are also within the scope of rights of the present invention.

What is claimed is:

1. A method of dividing a reticle pattern to implement a target reticle larger than a unit bare reticle through application of the unit bare reticle, the method comprising:
a basic operation of acquiring target-reticle data by inputting a wiring pattern and an outermost boundary corresponding to a conductive layer to be formed;
a line-extraction operation of extracting, within the target-reticle data, a plurality of boundary lines disposed in spaces where the wiring pattern is absent or corresponding to the outermost boundary of the target-reticle data;
an area-extraction operation of generating a candidate pool by producing a plurality of single-closed-curve sets, each single-closed-curve set comprising a plurality of single closed curves obtained by connecting the boundary lines and covering an entire area of the target-reticle data;
a verification operation of excluding, from the candidate pool, any single-closed-curve set in which at least one single closed curve is not located within the unit bare reticle; and
an output operation of outputting, from the candidate pool, the single-closed-curve sets in ascending order of the number of single closed curves contained therein,
whereby a unit-reticle set having outer shapes corresponding to the single-closed-curve set is prepared and a divided target reticle is implemented.

2. The method of claim 1,
wherein the wiring pattern comprises a linear-wire pattern and a via-pad-type wiring pattern, and the line-extraction operation comprises:
a first-boundary-extraction procedure of extracting a first-type boundary line at a midpoint between a first linear wire and an adjacent second linear wire;
a second-boundary-extraction procedure of extracting, between a third linear wire and an adjacent via-pad-type wire, a second-type boundary line that runs along the third linear wire at a predetermined spacing from the third linear wire; and
a third-boundary-extraction procedure of extracting, between adjacent via-pad-type wires, a third-type boundary line that connects, by the shortest path, opposite ends of the first-type boundary line, opposite ends of the second-type boundary line, or portions of the outermost boundary.

3. The method of claim 2,
wherein, when the area-extraction operation fails to derive a single-closed-curve set,
an extended-boundary-line extraction procedure is carried out in which an extended first-type boundary line and an extended second-type boundary line are extracted by respectively extending the first-type boundary line and the second-type boundary line, in straight lines, to a point that penetrates one wire, and
the area-extraction operation is then performed again on the basis of a plurality of boundary lines comprising the extended first-type boundary line, the extended second-type boundary line, and the third-type boundary line.

4. The method of claim 3,
wherein, when the re-performed area-extraction operation still fails to derive a single-closed-curve set,
the extended-boundary-line extraction procedure is applied such that the extended boundary lines are prolonged to a point that penetrates n wires, the extended-boundary-line extraction procedure and the area-extraction operation being re-performed, and
n is sequentially applied as an integer of 2 or greater.

5. The method of claim 4,
wherein the output operation further outputs whether the extended-boundary-line extraction procedure has been performed.

6. The method of claim 2,
wherein, in the first-boundary-extraction procedure, a space between the first linear wire and the second linear wire has a width at least three times the smaller one of widths of the first and second linear wires.

7. A reticle having a reticle pattern such that a target reticle larger than a unit bare reticle is implemented through application of the unit bare reticle, comprising:
a first unit reticle and a second unit reticle that are located adjacent to each other,
wherein the first unit reticle has a first-to-second connection surface that is in contact with the second unit reticle,
the second unit reticle has a second-to-first connection surface that is in contact with the first unit reticle,
the first unit reticle and the second unit reticle are connected to each other and have a linear pattern passing through the first-to-second connection surface and the second-to-first connection surface,
the linear pattern disposed on the first-to-second connection-surface side of the first unit reticle is a first-side linear pattern,
the linear pattern disposed on the second-to-first connection-surface side of the second unit reticle is a second-side linear pattern,
a first-to-second stitching region is disposed at an edge on the first-to-second connection-surface side of the first unit reticle,
a pattern disposed in the first-to-second stitching region and connected to the first-side linear pattern is a first-to-second stitching linear pattern,
the first-to-second stitching linear pattern has one end directly connected to the first-side linear pattern and the other end directly connected to the first-to-second connection surface,
the first-to-second stitching linear pattern comprises
linear patterns extending from the one end to the other end such that distances between the linear patterns as a whole gradually increase, and
a width of the linear pattern at the other end is larger than a width of the linear pattern at the one end,
a second-to-first stitching region is disposed at an edge on the second-to-first connection-surface side of the second unit reticle,
a pattern disposed in the second-to-first stitching region and connected to the second-side linear pattern is a second-to-first stitching linear pattern,
the second-to-first stitching linear pattern has one end directly connected to the second-side linear pattern and the other end directly connected to the second-to-first connection surface,
the second-to-first stitching linear pattern comprises
linear patterns extending from the one end to the other end such that distances between the linear patterns as a whole gradually increase, and
a width of the linear pattern at the other end is larger than a width of the linear pattern at the one end,
and, when the first unit reticle and the second unit reticle come into contact with each other, the other end of the first-to-second stitching linear pattern and the other end of the second-to-first stitching linear pattern come into contact with each other so that the first-side linear pattern and the second-side linear pattern are connected.

8. The reticle of claim 7,
wherein a width of the linear pattern at the other end is obtained by expanding a width of the linear pattern at the one end by 1 μm to 5 μm on each of both sides.

9. The reticle of claim 7,
wherein the first unit reticle further comprises a first-side via pattern,
the first-side via pattern comprises
a first-side via and a first-side pad surrounding the first-side via,
a diameter of the first-side pad is 3 μm to 15 μm larger than a diameter of the first-side via,
and a distance between the first-side pad and a neighboring other via pad or another linear pattern is 2 μm or more.

10. The reticle of claim 9,
wherein a distance between an edge of the first-side pad and the first-to-second connection surface is 2.5 μm or more.
